(19) United States
(12) Patent Application Publication
(10) Pub. No.: US 2016/0079980 A1
(43) Pub. Date: Mar. 17, 2016

(54) BUFFER CIRCUIT

(71) Applicant: Kabushiki Kaisha Toshiba, Tokyo (JP)

(72) Inventors: Katsue Kawakyu, Kawasaki Kanagawa (JP); Masaru Mizuta, Kamakura Kanagawa (JP)

(21) Appl. No.: 14/645,359

(22) Filed: Mar. 11, 2015

(30) Foreign Application Priority Data
Sep. 16, 2014 (JP) 2014-188277

(51) Int. Cl. H03K 19/0185

(52) U.S. Cl. CPC H03K 19/018521

(57) ABSTRACT

A first logic inversion unit generates an input inversion signal and a buffer unit generates a signal having a same logic as that of the input inversion signal. The first logic inversion unit includes first and second MOS transistors. The first and second MOS transistors have conductivity types different from each other. The buffer unit includes third to sixth MOS transistors. The third and fourth MOS transistors are connected in cascade between a third reference potential and an output node of the buffer unit and have conductivity types different from each other. The fifth and sixth MOS transistors are connected in cascade between the output node of the buffer unit and a fourth reference potential and have conductivity types different from each other.

### CROSS REFERENCE TO RELATED APPLICATIONS

This application is based upon and claims the benefit of priority from the prior Japanese Patent Application No. 2014-188277, filed on Sep. 16, 2014, the entire contents of which are incorporated herein by reference.

### FIELD

Embodiments described herein relate generally to a buffer circuit.

### BACKGROUND

A buffer circuit is constituted, for example, by connecting a PMOS transistor and an NMOS transistor in cascade between a power supply terminal and a ground terminal and connecting gates of the transistors to an input terminal and drains of the transistors to a common output terminal. According to a logic of an input signal, either the PMOS transistor or the NMOS transistor is turned ON. When the input signal has an intermediate potential, neither the PMOS transistor nor the NMOS transistor in the buffer circuit becomes a complete OFF-state and becomes a weak ON-state. This adversely causes a through current to flow in the buffer circuit from the power supply terminal to the ground terminal via the PMOS transistor and the NMOS transistor. As the input signal is higher-speed, the through current becomes larger and accordingly power consumption of the buffer circuit is increased.

### BRIEF DESCRIPTION OF THE DRAWINGS

FIG. 1 is a circuit diagram of a buffer circuit 1 according to a first embodiment;

FIG. 2 is a schematic diagram showing a correspondence relation between signal levels of the buffer circuit 1 shown in FIG. 1 and switching operation states;

FIG. 3 is a schematic diagram showing a switching operation state of the buffer circuit 1 shown in FIG. 1 in a case where the input signal IN has an intermediate potential;

FIG. 4 is a circuit diagram of the buffer circuit 1 according to the second embodiment;

FIG. 5 is a schematic diagram showing a switching operation state of the buffer circuit 1 shown in FIG. 4 in a case where the input signal is at an intermediate potential;

FIG. 6 shows CPD and the maximum through current as electrical characteristics of the buffer circuit 1;

FIG. 7 is an output waveform diagram of the buffer circuits 1;

FIG. 8 shows a circuit configuration of a buffer circuit according to the comparative example; and

FIG. 9 is a graph showing a comparison of through currents among the buffer circuits shown in FIGS. 1 and 4 and the buffer circuit shown in FIG. 8.

### DETAILED DESCRIPTION

A buffer circuit according to an embodiment includes a first logic inversion unit and a buffer unit. The first logic inversion unit generates an input inversion signal having an inversion of a logic of an input signal. The buffer unit generates a signal having a same logic as that of the input inversion signal. The first logic inversion unit includes a first MOS transistor and a second MOS transistor. The first MOS transistor is connected between a first reference potential and an output node of the first logic inversion unit. The second MOS transistor is connected between the output node of the first logic inversion unit and a second reference potential and has a conductivity type different from that of the first MOS transistor. The buffer unit comprises a third MOS transistor, a fourth MOS transistor, a fifth MOS transistor, and a sixth MOS transistor. The third and fourth MOS transistors are connected in cascade between a third reference potential and an output node of the buffer unit and have conductivity types different from each other. The fifth and sixth MOS transistors are connected in cascade between the output node of the buffer unit and a fourth reference potential and have conductivity types different from each other.

Embodiments of the present invention are explained below with reference to the accompanying drawings. In the following embodiments, characteristic configurations and operations of the buffer circuit are explained; however, configurations and operations for which explanations are omitted may be also included in the buffer circuit. These omitted configurations and operations are also included in the scope of the embodiments.

### First Embodiment

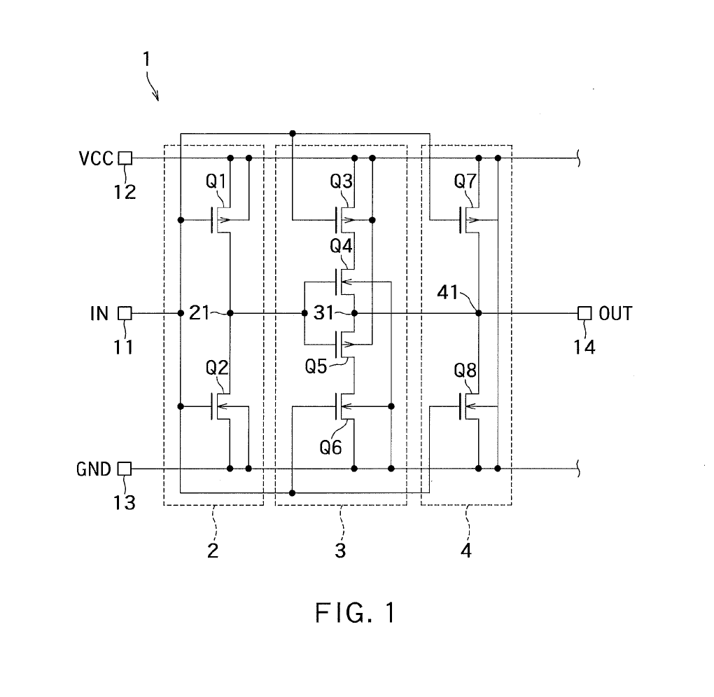

FIG. 1 is a circuit diagram of a buffer circuit 1 according to a first embodiment. The buffer circuit 1 shown in FIG. 1 buffers an input signal IN such as a clock signal and outputs the input signal IN. The buffer circuit 1 shown in FIG. 1 can be used, for example, as an output circuit for driving a load. The input signal IN is not limited to a clock signal and various digital signals can be applied thereto.

The buffer circuit 1 includes a first logic inversion unit 2, a buffer unit 3, and a second logic inversion unit 4 in this order from the input side. The first logic inversion unit 2 generates an input inversion signal having an inversion of a logic of the input signal IN and outputs the generated input inversion signal to the buffer unit 3 provided at the subsequent stage. The buffer unit 3 generates a signal having the same logic as that of the input inversion signal generated by the first logic inversion unit 2 and outputs the generated signal to an output node 41 of the second logic inversion unit 4 provided at the subsequent stage. The second logic inversion unit 4 generates a signal having an inversion of the logic of the input signal IN and outputs the generated signal to the output node 41 of the second logic inversion unit 4. An output node 31 of the buffer unit 3 and the output node 41 of the second logic inversion unit 4 are both connected to an output terminal 14 of the buffer circuit 1. In FIG. 1, a signal of the output terminal 14 of the buffer circuit 1 is an output signal OUT.

An internal configuration of the buffer circuit 1 and an operation thereof are explained in detail below.

### (First Logic Inversion Unit 2)

The first logic inversion unit 2 has a first MOS transistor Q1 and a second MOS transistor Q2 having conductivity types different from each other. The first MOS transistor Q1 is connected between a first reference potential and an output node 21 of the first logic inversion unit 2 and is, for example, a PMOS transistor Q1. The second MOS transistor Q2 is connected between the output node 21 of the first logic inversion unit 2 and a second reference potential and is, for example, an NMOS transistor Q2 having a conductivity type different from that of the first MOS transistor Q1. Gate widths of the first MOS transistor Q1 and the second MOS transistor Q2 are set smaller than those of a third MOS transistor (first transistor) Q3, a fourth MOS transistor (second transistor) Q4, a fifth MOS transistor (third transistor) Q5, and a sixth MOS transistor (fourth transistor) Q6, which are explained later.

In FIG. 1, the first reference potential is a power supply potential (first common potential) VCC and the second reference potential is a ground potential (second common potential) GND. The power supply potential VCC is supplied from a power supply terminal 12 and the ground potential GND is connected to a ground terminal 13. A gate of the first MOS transistor Q1 is connected to an input terminal 11 of the buffer circuit 1. A source of the first MOS transistor Q1 is connected to the power supply terminal 12. A drain of the first MOS transistor Q1 is connected to the output node 21 of the first logic inversion unit 2.

The first MOS transistor Q1 configured in this way is turned ON and causes a current to flow from the side of the power supply terminal 12 to the side of the output node 21 of the first logic inversion unit 2 when the input signal IN has a low potential, that is, a low level.

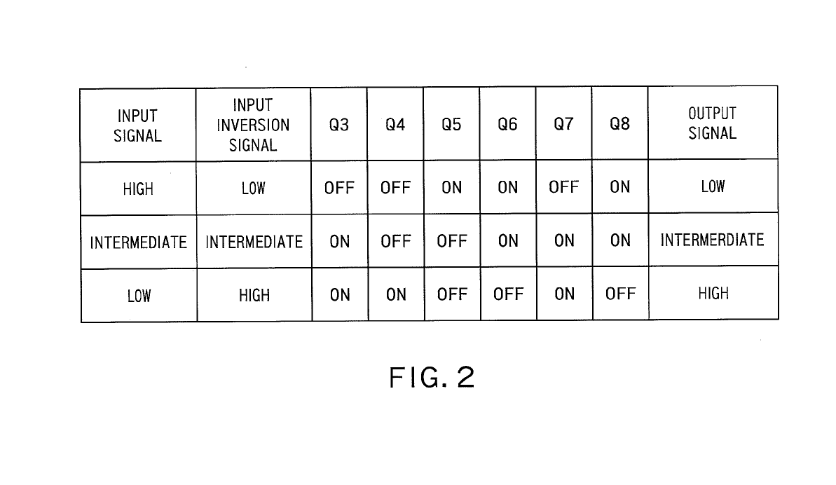

FIG. 2 is a schematic diagram showing a correspondence relation between signal levels of the buffer circuit 1 shown in FIG. 1 and switching operation states. As shown in FIG. 2, by a switching operation of the first MOS transistor Q1 as described above, the first logic inversion unit 2 can generate an input inversion signal at a high potential as the input inversion signal when a logic of the input signal IN is at a low potential. Q3 to Q8 in FIG. 2 denote MOS transistors in the buffer unit 3 and in the second logic inversion unit 4, which are explained later.

Meanwhile, the first MOS transistor Q1 is turned ON when the input signal IN has a low potential, that is, a low level and is turned OFF when the input signal IN has a high potential, that is, a high level. The first MOS transistor Q1 is not completely turned OFF and becomes a weak ON-state when the input signal IN has an intermediate potential.

The second MOS transistor Q2 is connected between the output node 21 of the first logic inversion unit 2 and the ground potential GND. A gate of the second MOS transistor Q2 is connected to the input terminal 11. A source of the second MOS transistor Q2 is connected to the ground potential GND. A drain of the second MOS transistor Q2 is connected to the output node 21 of the first logic inversion unit 2.

The second MOS transistor Q2 configured in this way operates complementarily with the first MOS transistor Q1. Specifically, the second MOS transistor Q2 is turned ON and causes a current to flow from the side of the output node 21 of the first logic inversion unit 2 to the side of the ground terminal 13 when the input signal IN has a high potential. Accordingly, as shown in FIG. 2, the first logic inversion unit 2 can generate an input inversion signal at a low potential when a logic of the input signal IN is at a high potential. Meanwhile, the second MOS transistor Q2 is turned OFF when the input signal IN has a low potential.

When the input signal IN has an intermediate potential, the second MOS transistor Q2 does not become a complete OFF-state. That is, when the input signal IN has an intermediate potential, the second MOS transistor Q2 becomes a weak ON-state at the same time as the first MOS transistor Q1. This causes a through current to flow in the buffer circuit 1 from the side of the power supply terminal 12 to the side of the ground terminal 13 via the first MOS transistor Q1 and the second MOS transistor Q2. However, because the gate widths of the first MOS transistor Q1 and the second MOS transistor Q2 are sufficiently small, the through current is sufficiently small.

As described above, the first logic inversion unit 2 is an inverter constituted by the first MOS transistor Q1 and the second MOS transistor Q2. The first logic inversion unit 2 can be a CMOS (Complementary MOS) inverter.

### (Buffer Unit 3)

The buffer unit 3 has the third to sixth MOS transistors Q3 to Q6. The third and fourth MOS transistors Q3 and Q4 are transistors connected in cascade between a third reference potential and the output node 31 of the buffer unit 3 and having conductivity types different from each other. The third MOS transistor Q3 is, for example, a PMOS transistor Q3 and the fourth MOS transistor Q4 is, for example, an NMOS transistor Q4. The fifth and sixth MOS transistors Q5 and Q6 are transistors connected in cascade between the output node 31 of the buffer unit 3 and a fourth reference potential and having conductivity types different from each other. The fifth MOS transistor Q5 is, for example, a PMOS transistor Q5 and the sixth MOS transistor Q6 is, for example, an NMOS transistor Q6.

In FIG. 1, the third reference potential is the power supply potential (first common potential) VCC and the fourth reference potential is the ground potential (second common potential) GND.

A gate of the third MOS transistor Q3 is connected to the input terminal 11. A source of the third MOS transistor Q3 is connected to the power supply terminal 12. A drain of the third MOS transistor Q3 is connected to a drain of the fourth MOS transistor Q4.

The third MOS transistor Q3 configured in this way is turned ON when the input signal IN has a low potential and is turned OFF when the input signal IN has a high potential as shown in FIG. 2. The third MOS transistor Q3 is not completely turned OFF and becomes a weak ON-state when the input signal IN has an intermediate potential.

A gate of the fourth MOS transistor Q4 is connected to the output node 21 of the first logic inversion unit 2. A source of the fourth MOS transistor Q4 is connected to the output node 31 of the buffer unit 3.

As shown in FIG. 2, the fourth MOS transistor Q4 receives an input inversion signal at a high potential as an input to the gate thereof and is turned ON when the input signal IN has a low potential and receives an input inversion signal at a low potential as an input to the gate thereof and is turned OFF when the input signal IN has a high potential. When the input signal IN has an intermediate potential, the fourth MOS transistor Q4 becomes an OFF-state.

A gate of the fifth MOS transistor Q5 is connected to the output node 21 of the first logic inversion unit 2. A source of the fifth MOS transistor Q5 is connected to the output node 31 of the buffer unit 3. A drain of the fifth MOS transistor Q5 is connected to a drain of the sixth MOS transistor Q6.

As shown in FIG. 2, the fifth MOS transistor Q5 receives an input inversion signal at a low potential as an input to the gate and is turned ON when the input signal IN has a high potential and receives an input inversion signal at a high potential as an input to the gate and is turned OFF when the input signal IN has a low potential. The fifth MOS transistor Q5 becomes an OFF-state when the input signal IN has an intermediate potential.

A gate of the sixth MOS transistor Q6 is connected to the input terminal 11. A source of the sixth MOS transistor Q6 is connected to the ground terminal 13.

The sixth MOS transistor Q6 configured in this way is turned ON when the input signal IN has a high potential and is turned OFF when the input signal IN has a low potential as shown in FIG. 2. The sixth MOS transistor Q6 is not completely turned OFF and becomes a weak ON-state when the input signal IN has an intermediate potential.

### (Second Logic Inversion Unit 4)

The second logic inversion unit 4 has seventh and eighth MOS transistors Q7 and Q8. The seventh MOS transistor Q7 is connected between a fifth reference potential and the output node 41 of the second logic inversion unit 4 and is, for example, a PMOS transistor Q7. The eighth MOS transistor Q8 is connected between the output node 41 of the second logic inversion unit 4 and a sixth reference potential and is, for example, an NMOS transistor Q8. Gate widths of the seventh MOS transistor Q7 and the eighth MOS transistor Q8 are set smaller than those of the MOS transistors Q3 to Q6 in the buffer unit 3 described above.

In FIG. 1, the fifth reference potential is the power supply potential (first common potential) VCC and the sixth reference potential is the ground potential (second common potential) GND.

The seventh MOS transistor Q7 configured in this way is turned ON and causes a current to flow from the side of the power supply terminal 12 to the side of the output node 41 of the second logic inversion unit 4 when the input signal IN has a low potential as shown in FIG. 2. Accordingly, when the logic of the input signal IN has a low potential, the second logic inversion unit 4 generates a high-potential signal having an inversion of the logic of the input signal IN. On the other hand, when the input signal IN has a high potential, the seventh MOS transistor Q7 is turned OFF. The seventh MOS transistor Q7 is not completely turned OFF and becomes a weak ON-state when the input signal IN has an intermediate potential.

The eighth MOS transistor Q8 is connected between the output node 41 of the second logic inversion unit 4 and the ground potential GND. A gate of the eighth MOS transistor Q8 is connected to the input terminal 11. A source of the eighth MOS transistor Q8 is connected to the ground terminal 13. A drain of the eighth MOS transistor is connected to the output node 41 of the second logic inversion unit 4.

The eighth MOS transistor Q8 configured in this way operates complementarily with the seventh MOS transistor Q7. Specifically, the eighth MOS transistor Q8 is turned ON and causes a current to flow from the side of the output node 41 of the second logic inversion unit 4 to the side of the ground terminal 13 when the input signal IN has a high potential as shown in FIG. 2. Accordingly, when the logic of the input signal IN has a high potential, the second logic inversion unit 4 generates a low-potential signal having an inversion of the logic of the input signal IN. On the other hand, when the input signal IN has a low potential, the eighth MOS transistor Q8 is turned OFF. When the input signal IN has an intermediate potential, the eighth MOS transistor Q8 does not become a complete OFF-state. That is, when the input signal IN has an intermediate potential, the eighth MOS transistor Q8 becomes a weak ON-state at the same as the seventh MOS transistor Q7.

As described above, the second logic inversion unit 4 is an inverter constituted by the seventh MOS transistor Q7 and the eighth MOS transistor Q8. The second logic inversion unit 4 can be a CMOS inverter.

As an operation example of the entire buffer circuit 1, an operation example in a case where the input signal IN has an intermediate potential is explained next.

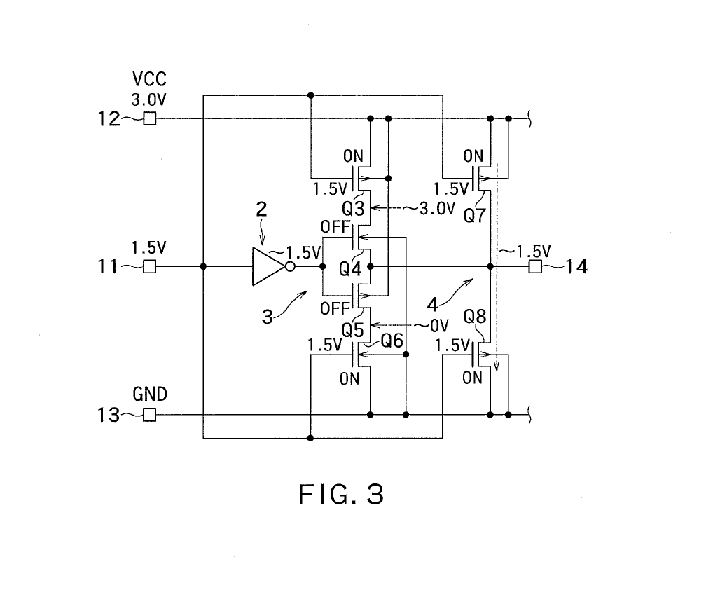

FIG. 3 is a schematic diagram showing a switching operation state of the buffer circuit 1 shown in FIG. 1 in a case where the input signal IN has an intermediate potential. In FIG. 3, the first logic inversion unit 2 is represented by a symbol of an inverter. In the example shown in FIG. 3, the power supply potential is 3.0 volts and the input signal IN at an intermediate potential is at 1.5 volts. In FIG. 3, the symbol “˜” attached to the head of a voltage value indicates that the voltage value after the symbol is an approximate value. For example, in FIG. 3, it is indicated that a voltage “˜3.0 volts” of the drain of the third MOS transistor Q3 is about 3.0 volts. Furthermore, in FIG. 3, it is indicated that a voltage “˜0 volt” of the drain of the sixth MOS transistor Q6 is about 0 volt.

As shown in FIG. 3, when the input signal IN is at 1.5 volts, an output voltage of the first logic inversion unit 2 is about 1.5 volts. The reason is as follows. Because the first MOS transistor Q1 and the second MOS transistor Q2 in the first logic inversion unit 2 both become a weak ON-state as shown in FIG. 1, the potential of the output of the first logic inversion unit 2, which is the connection node 21 between the transistors Q1 and Q2, becomes about 1.5 volts, that is, the potential is an intermediate potential between the power supply potential VCC (=3.0 volts) and the ground potential GND (=0 volt).

Therefore, the gate potentials of the fourth MOS transistor Q4 and the fifth MOS transistor Q5 in the buffer unit 3 are also about 1.5 volts. Meanwhile, 1.5 volts as an intermediate potential is input to the gates of the third MOS transistor Q3 and the sixth MOS transistor Q6 and thus the transistors Q3 and Q6 become a weak ON-state. Accordingly, the drain of the third MOS transistor Q3, that is, the drain of the fourth MOS transistor Q4 becomes at about 3.0 volts and the drain of the sixth MOS transistor Q6, that is, the drain of the fifth MOS transistor Q5 becomes at about 0 volt. Meanwhile, because 1.5 volts as an intermediate potential is input to the gates of the seventh MOS transistor Q7 and the eighth MOS transistor Q8 in the second logic inversion unit 4, the transistors Q7 and Q8 become a weak ON-state. Therefore, a through current (see the broken line in FIG. 3) flows between the MOS transistors Q7 and Q8 and thus the output node 41 (see FIG. 1) and the output node 31 (see FIG. 1) become at about 1.5 volts. Accordingly, a gate-source voltage does not satisfy the condition to turn the transistors Q4 and Q5 ON and thus the transistors Q4 and Q5 are turned OFF.

In this manner, when the input signal IN is at 1.5 volts, meaning that the potential is an intermediate potential, the third MOS transistors Q3 and the sixth MOS transistors Q6 are turned ON in the buffer unit 3 while the fourth MOS transistor Q4 and the fifth MOS transistor Q5 are turned OFF. Accordingly, a through current is prevented from flowing in the buffer unit 3.

On the other hand, a through current (see the broken line in FIG. 3) flows in the second logic inversion unit 4. Because the gate widths of the seventh MOS transistor Q7 and the eighth MOS transistor Q8 are sufficiently smaller than those of the MOS transistors Q3 to Q6 in the buffer unit 3, the through current is sufficiently small. Similarly, while a through current flows also in the first MOS transistor Q1 and the second MOS transistor Q2 in the first logic inversion unit 2, the gate widths of the transistors Q1 and Q2 are sufficiently smaller than those of the transistors Q3 to Q6 and thus the through current hardly causes problems.

As described above, the buffer circuit 1 according to the first embodiment includes the buffer unit 3 between the first logic inversion unit 2 and the second logic inversion unit 4 that perform logic inverting of an input signal and the gate widths of the MOS transistors Q3 to Q6 in the buffer unit 3 are set larger than those of the MOS transistors Q1, Q2, Q7, and Q8 in the first and second logic inversion units 2 and 4. When an intermediate potential is input to the buffer circuit 1, the MOS transistors Q4 and Q5 in the buffer unit 3 are turned OFF to prevent a through current from flowing in the buffer unit 3. In this way, provision of the buffer unit 3 having the larger gate widths enables a high-speed operation and, even when the input signal at an intermediate potential is input thereto, no through current flows in the buffer unit 3, whereby power consumption can be reduced.

### Second Embodiment

The buffer circuit 1 according to a second embodiment is explained next. In the following explanations, constituent elements of the buffer circuit 1 according to the second embodiment corresponding to those of the buffer circuit 1 according to the first embodiment are denoted by like reference numerals and redundant explanations thereof will be omitted.

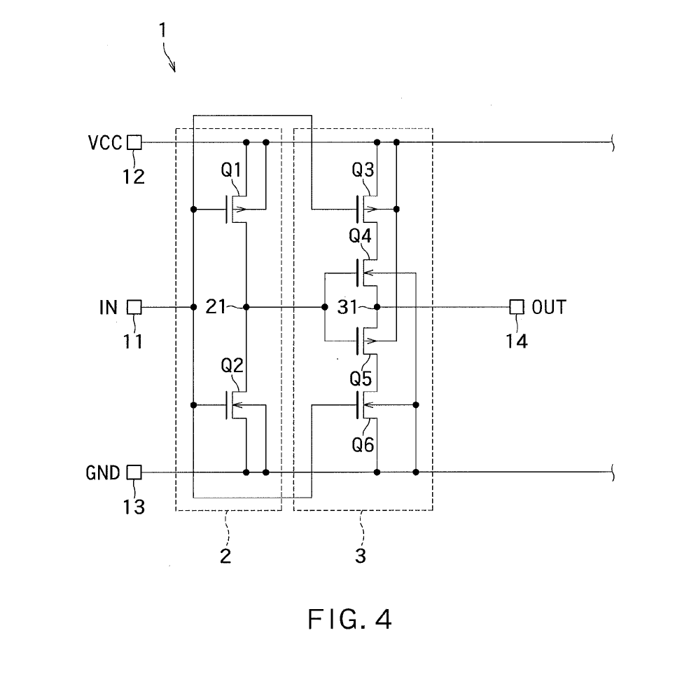

FIG. 4 is a circuit diagram of the buffer circuit 1 according to the second embodiment. The buffer circuit 1 shown in FIG. 4 is obtained by omitting the second logic inversion unit 4 from the buffer circuit 1 shown in FIG. 1.

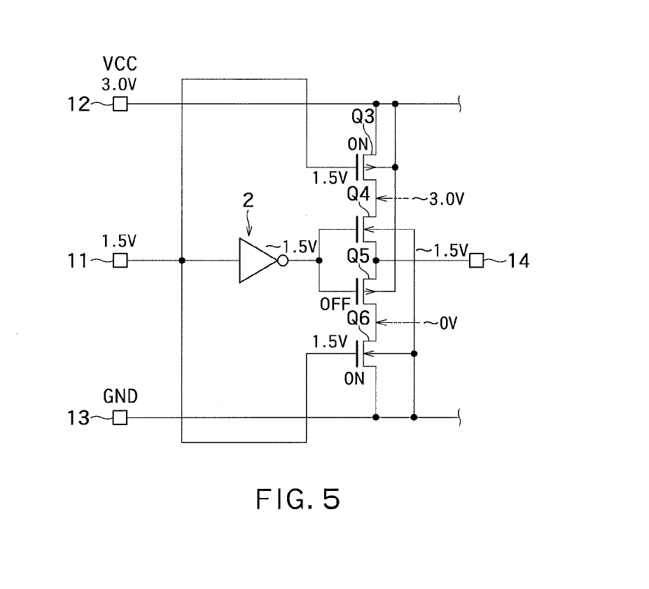

FIG. 5 is a schematic diagram showing a switching operation state of the buffer circuit 1 shown in FIG. 4 in a case where the input signal is at an intermediate potential. As can be seen from a comparison between FIGS. 3 and 5, operations of the first logic inversion unit 2 and the buffer unit 3 in the buffer circuit 1 according to the second embodiment are the same as those of the buffer circuit 1 shown in FIG. 1. Therefore, no through current occurs in the buffer unit 3 in a case where the input signal IN is at an intermediate potential (1.5 volts). According to the second embodiment, similarly to the first embodiment, power consumption can be suppressed.

More specific operating characteristics of the buffer circuits 1 according to the first and second embodiments are explained next based on simulation results of the operating characteristics.

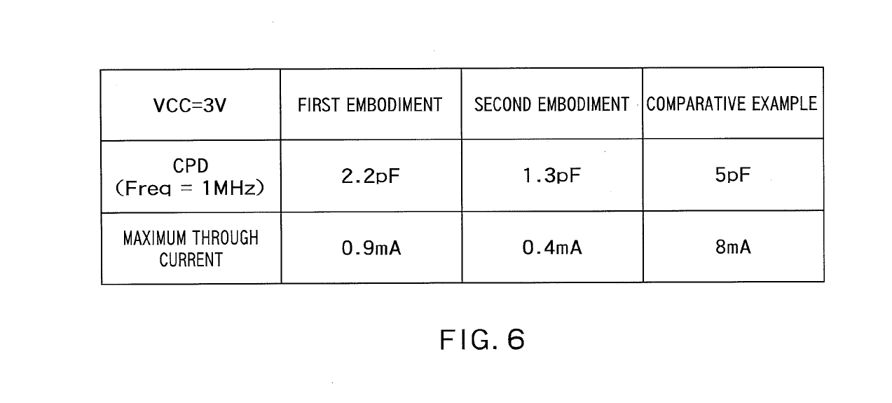

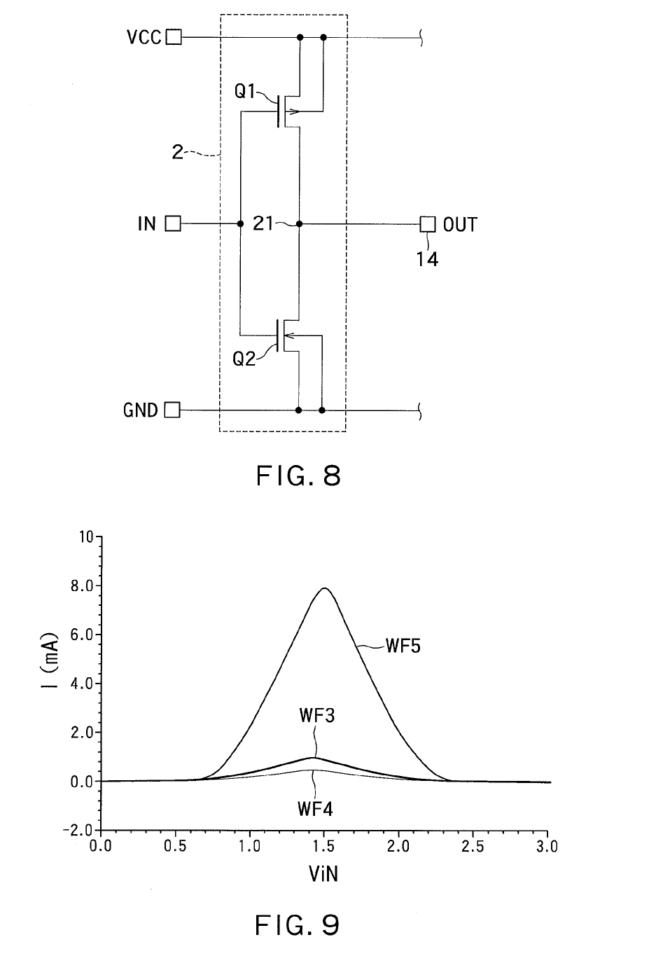

FIG. 6 shows CPD (capacitive power dissipation) and the maximum through current as electrical characteristics of the buffer circuit 1. In FIG. 6, in addition to the electrical characteristics of the buffer circuits 1 shown in FIG. 1 (the first embodiment) and in FIG. 4 (the second embodiment) described above, electrical characteristics of a comparative example are also shown. FIG. 8 shows a circuit configuration of a buffer circuit according to the comparative example. The buffer circuit shown in FIG. 8 has only the first logic inversion unit 2 in FIG. 1 and the output node 21 of the first logic inversion unit 2 is connected to the output terminal 14 of the buffer circuit.

The CPD is a parameter being a measure of an operation consumption current ICC′ as indicated by the following expression.

ICC′=CPD×VCC×freq+ICC (1)

In the expression (1), VCC denotes a power supply voltage, freq denotes an operating frequency of the buffer circuit, and ICC denotes a static consumption current.

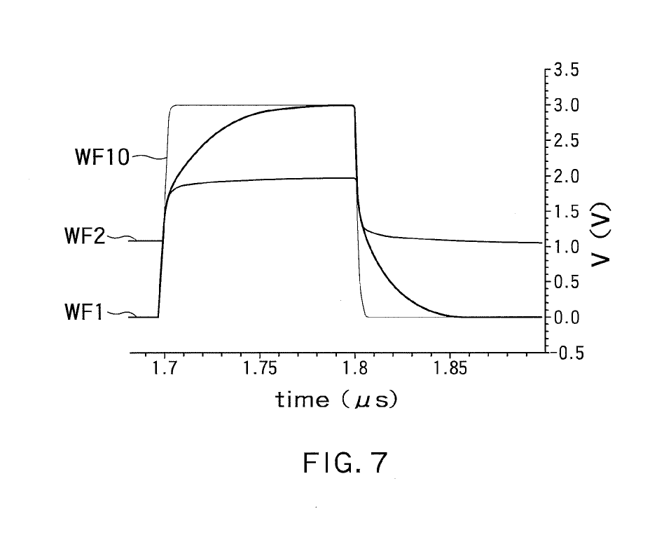

FIG. 7 is an output waveform diagram of the buffer circuits 1. FIG. 7 shows a simulation result WF2 of an output waveform of the buffer circuit 1 according to the second embodiment as well as a simulation result WF1 of an output waveform of the buffer circuit 1 according to the first embodiment and a simulation result WF10 of an output waveform of the buffer circuit according to the comparative example.

The condition of the power supply voltage VCC for obtaining the characteristics as shown in FIGS. 6 and 7 is 3.0 volts and the condition of the ground potential GND therefor is 0 volt. The conditions of the gate widths of the first MOS transistor Q1, the second MOS transistor Q2, the third MOS transistor Q3, the fourth MOS transistor Q4, the fifth MOS transistor Q5, the sixth MOS transistor Q6, the seventh MOS transistor Q7, and the eighth MOS transistor Q8 are 10 micrometers, 5 micrometers, 400 micrometers, 200 micrometers, 400 micrometers, 200 micrometers, 10 micrometers, and 5 micrometers, respectively. The input signal IN is a clock signal. The condition of a load capacitance CL is 30 picofarads and the condition of the operating frequency (freq) is 1 megahertz.

As shown in FIG. 6, the buffer circuits 1 according to the first embodiment and the second embodiment acquired better results than that of the buffer circuit according to the comparative example with respect to the CPD and the maximum through current. That is, the buffer circuits 1 according to the first and second embodiments can suppress power consumption as compared to the comparative example.

The signal waveforms WF1, WF2, and WF10 shown in FIG. 7 are the output waveforms of the buffer circuits 1 according to the first and second embodiments and the buffer circuit according to the comparative example, respectively. As can be understood from these signal waveforms, provision of the second logic inversion unit 4 generates an output signal in full swing between the maximum potential (3.0 volts) and the minimum potential (0 volt) in the first embodiment. In this manner, because the amplitude of the output signal is large, the buffer circuit 1 according to the first embodiment can drive a load requiring a high voltage.

Furthermore, as shown in FIG. 7, while the output waveforms WF1 and WF2 of the buffer circuits 1 according to the first and second embodiments abruptly rise or fall from the start of changes of the signal to an intermediate potential, changes after the intermediate potential are gentle. The reason is as follows. Immediately after signal switching, the input signal temporarily becomes at the intermediate potential and thus the MOS transistors Q4 and Q5 in the buffer unit 3 are turned OFF and the output potential of the buffer circuit 1 also becomes the intermediate potential promptly as shown in FIGS. 3 and 5. When an output logic of the first logic inversion unit 2 is then determined, the output potential of the buffer unit 3 changes accordingly. On the other hand, in the buffer circuit according to the comparative example, because the input inversion signal is obtained from a clock signal as the input, the output waveform WF10 abruptly rises to the maximum amplitude or falls to the minimum amplitude. Abrupt rise or fall of the output signal is likely to cause noises. In contrast, according to the buffer circuits 1 in the first and second embodiments, the output signal can include portions that abruptly rise or fall and portions that gently rise or fall unlike the buffer circuit in the comparative example. Therefore, the buffer circuits 1 can achieve low switching noise characteristics while addressing a high-speed operation.

FIG. 9 is a graph showing a comparison of through currents among the buffer circuits shown in FIGS. 1 and 4 and the buffer circuit shown in FIG. 8. The horizontal axis in FIG. 9 represents the input signal potential [V] of the buffer circuits and the vertical axis represents the through current [mA] flowing in the buffer circuits. A signal waveform WF3 in FIG. 9 is a through current waveform of the buffer circuit shown in FIG. 1, a signal waveform WF4 is a through current waveform of the buffer circuit shown in FIG. 4, and a signal waveform WF5 is a through current waveform of the buffer circuit shown in FIG. 8.

As can be seen from FIG. 9, the buffer circuits shown in FIGS. 1, 4, and 8 all have largest through currents when the input signal potential is an intermediate potential. The through current of the buffer circuit shown in FIG. 4 without the second logic inversion unit is the smallest and the through current of the buffer circuit shown in FIG. 1 is the second smallest. The buffer circuit shown in FIG. 8 without the buffer unit and the second logic inversion unit has an extremely-large through current.

The buffer circuits according to the first and second embodiments have a common point in having the buffer unit. As described above, the buffer unit is constituted by connecting the MOS transistors Q3 to Q6 in cascade between the power supply potential VCC and the ground potential GND. Among these MOS transistors, the MOS transistors Q4 and Q5 are configured to be always turned OFF when the input signal potential is an intermediate potential.

In this way, the buffer circuits according to the first and second embodiments can suppress the through current more reliably than the buffer circuit according to the comparative example by providing the buffer unit having a circuit configuration that prevents a through current from flowing at an intermediate potential.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A buffer circuit comprising:
a first logic inversion unit to generate an input inversion signal having an inversion of a logic of an input signal; and
a buffer unit to generate a signal identical to a logic of the input inversion signal, wherein
the first logic inversion unit comprises
a first MOS transistor connected between a first reference potential and an output node of the first logic inversion unit, and
a second MOS transistor connected between the output node of the first logic inversion unit and a second reference potential and having a conductivity type different from a conductivity type of the first MOS transistor, and
the buffer unit comprises
a third MOS transistor and a fourth MOS transistor connected in cascade between a third reference potential and an output node of the buffer unit and having conductivity types different from each other, and
a fifth MOS transistor and a sixth MOS transistor connected in cascade between the output node of the buffer unit and a fourth reference potential and having conductivity types different from each other.

2. The buffer circuit of claim 1, wherein the fourth and fifth MOS transistors are turned OFF when the input signal is at an intermediate potential at which the first and second MOS transistors and the third and sixth MOS transistors are all turned ON.

3. The buffer circuit of claim 1, wherein gate widths of the first and second MOS transistors are smaller than gate widths of the third to sixth MOS transistors.

4. The buffer circuit of claim 2, wherein gate widths of the first and second MOS transistors are smaller than gate widths of the third to sixth MOS transistors.

5. The buffer circuit of claim 1, comprising a second logic inversion unit to generate a signal having an inversion of the logic of the input signal, wherein
the second logic inversion unit comprises
a seventh MOS transistor connected between a fifth reference potential and an output node of the second logic inversion unit, and
an eighth MOS transistor connected between the output node of the second logic inversion unit and a sixth reference potential and having a conductivity type different from a conductivity type of the seventh MOS transistor.

6. The buffer circuit of claim 2, comprising a second logic inversion unit to generate a signal having an inversion of the logic of the input signal, wherein
the second logic inversion unit comprises
a seventh MOS transistor connected between a fifth reference potential and an output node of the second logic inversion unit, and
an eighth MOS transistor connected between the output node of the second logic inversion unit and a sixth reference potential and having a conductivity type different from a conductivity type of the seventh MOS transistor.

7. The buffer circuit of claim 3, comprising a second logic inversion unit to generate a signal having an inversion of the logic of the input signal, wherein
the second logic inversion unit comprises
a seventh MOS transistor connected between a fifth reference potential and an output node of the second logic inversion unit, and
an eighth MOS transistor connected between the output node of the second logic inversion unit and a sixth reference potential and having a conductivity type different from a conductivity type of the seventh MOS transistor.

8. The buffer circuit of claim 5, wherein gate widths of the seventh and eighth MOS transistors are smaller than gate widths of the third to sixth MOS transistors.

9. The buffer circuit of claim 6, wherein gate widths of the seventh and eighth MOS transistors are smaller than gate widths of the third to sixth MOS transistors.

10. The buffer circuit of claim 7, wherein gate widths of the seventh and eighth MOS transistors are smaller than gate widths of the third to sixth MOS transistors.

11. The buffer circuit of claim 5, wherein
the first, third, and fifth reference potentials are a first common potential, and
the second, fourth, and sixth reference potentials are a second common potential having a potential level different from a potential level of the first common potential.

12. The buffer circuit of claim 6, wherein
the first, third, and fifth reference potentials are a first common potential, and
the second, fourth, and sixth reference potentials are a second common potential having a potential level different from a potential level of the first common potential.

13. The buffer circuit of claim 7, wherein
the first, third, and fifth reference potentials are a first common potential, and
the second, fourth, and sixth reference potentials are a second common potential having a potential level different from a potential level of the first common potential.

14. The buffer circuit of claim 8, wherein
the first, third, and fifth reference potentials are a first common potential, and
the second, fourth, and sixth reference potentials are a second common potential having a potential level different from a potential level of the first common potential.

15. The buffer circuit of claim 9, wherein
the first, third, and fifth reference potentials are a first common potential, and
the second, fourth, and sixth reference potentials are a second common potential having a potential level different from a potential level of the first common potential.

16. The buffer circuit of claim 10, wherein
the first, third, and fifth reference potentials are a first common potential, and
the second, fourth, and sixth reference potentials are a second common potential having a potential level different from a potential level of the first common potential.

17. A buffer circuit comprising:
a first logic inversion unit to generate an input inversion signal having an inversion of a logic of an input signal, and
a buffer unit to generate a signal identical to a logic of the input inversion signal, wherein
the buffer unit comprises
a first transistor and a second transistor connected in cascade between a first potential and an output node of the buffer unit and having conductivity types different from each other, and
a third transistor and a fourth transistor connected in cascade between the output node of the buffer unit and a second potential and having conductivity types different from each other, and
at least one of the first to fourth transistors is turned OFF when an intermediate potential between the first potential and the second potential is input to the buffer unit.
